(19) United States
(12) Patent Application Publication
(10) Pub. No.: US 2002/0181215 A1
(43) Pub. Date: Dec. 5, 2002

(54) Midplane circuit board assembly

(76) Inventor: Russell W. Guenthner, Glendale, AZ (US)

Correspondence Address: Ronald J. Meetin, Skjerven Morrill LLP, Suite 700, 25 Metro Drive, San Jose, CA, 95110, US

(21) Appl. No.: 10/205,345

(22) Filed: Jul. 24, 2002

Related U.S. Application Data
(63) Continuation of application No. 09/860,343, filed on May 17, 2001, now abandoned.

(51) Int. Cl. H05K 1/14

(52) U.S. Cl. 361/784; 361/788

(57) ABSTRACT

A reconfigurable logic structure utilizes a midplane circuit board assembly having a plurality of reprogrammable logic boards mounted in a first direction on one side of the midplane circuit board and a plurality of programmable interconnect boards mounted in a second direction on an opposite side of the midplane circuit board. The logic and interconnect boards attach to the midplane circuit board through connectors which are surface mounted to the front and back sides of the midplane circuit board. The surface mounting of the midplane board connectors allows more dense electrical connections and increased density of midplane board routing compared to the prior art and is particularly useful in the construction of reprogrammable logic emulators and logic simulators because of the particular nature of the interconnects often needed in the construction of such machines.

### BACKGROUND

1. Field of the invention

The present invention relates to circuit board assemblies, and to providing electrical connections between a plurality of circuit boards using a midplane circuit board. More specifically, this invention relates to providing electrical connections between a plurality of circuit boards in which a large number of connections from each of these boards requires a large number of connections spread across a plurality of other boards.

2. Description of Related Art

Circuit-board level system complexity has dramatically increased due to advances in the integrated circuit and discrete component technology. Such advances provide products with improved functionality, performance, integration, and cost. However, they also make the system verification so complex as to become a significant bottleneck in the development process. Increasing logic design sizes have overrun the capabilities of traditional software-only simulation tools. Large software development teams working on embedded systems and system-on-chip (SoC) design projects typically do not have sufficient time to wait for new hardware to be fabricated to begin testing their designs.

To facilitate system verification, programmable interconnect systems have been developed that use programmable interconnects to quickly and cheaply facilitate construction of a model which will replicate system-level hardware functionality. Programmable interconnect chips are used in conjunction with either hardwired logic chips or chips containing programmable arrays of logic to build a model of a hardware design for purposes of testing a logic design before it is actually constructed as part of a fully realized system. Typically, the size and complexity of the design requires interconnect paths from each logic chip to many other logic chips. In such a model, programmable interconnect chips provide a changeable mechanism for interconnecting either fixed or programmable logic.

An example of a system with similar connection requirements is a classical telephone switching system. A telephone switching system is set up with sufficient interconnect wiring such that any customer can be connected to any other customer. For large numbers of customers the complexity of the routing problem can grow as the square of the number of lines involved. The theory for calculating the complexity and some mechanisms and solutions to such problems were widely discussed in the literature surrounding the construction of telephone systems. Two classic references often discussed in university courses on these subjects are V. E. BENES, MATHEMATICAL THEORY OF CONNECTING NETWORKS AND TELEPHONE TRAFFIC 136-158 (1965) and Charles Clos, A Study of Non-Blocking Switching Networks, THE BELL SYS. TECHNICAL J., Mar. 1953, at 406. In these papers, the mechanism for interconnect is called a “crossbar”.

In the design of a system for providing reprogrammable interconnect, one card of logic may require connection to many other cards of logic, and those cards in turn may also be connected to many other cards of logic. The interconnects between cards are often provided by a backplane board that provides both physical support and routing between logic cards. A backplane board which provides for insertion of boards on both sides is called a “midplane” board.

The prior art uses different approaches to interconnect boards.

The Aptix MP4 System contains field programmable interconnect chips (“FPICs”) on a board which serves as a backplane for the interconnection of smaller boards containing either fixed or programmable logic. The overall interconnectability is limited by the size and the number of layers of the backplane board, and also by the area occupied by the connectors between the backplane and the smaller boards.

U.S. Pat. No. 4,876,630 on an invention of Dara describes another approach which utilizes a mid-plane board for interconnecting a first set of circuit boards to a second set of circuit boards using pins which project outwardly equally on both sides of the board. The circuit boards have edge connectors which are connected to these pins. The circuit boards on the two sides of the midplane board are arranged in a pattern such that the boards on opposite sides are orthogonal to each other. This provides a natural routing path to allow a board on one side to connect to all the boards on the opposite side of the midplane board.

Similarly, U.S. Pat. Nos. 5,887,158 and 5,352,123 on inventions of Sample et al. describe a midplane and interconnecting system for interconnecting large numbers of signals from printed circuit boards. These patents describe a midplane printed circuit board having a plurality of first connectors oriented in a first direction on one side of the midplane, and a plurality of second connectors on an opposite side of the midplane oriented in a second direction orthogonal to the first direction. In this manner, the edge of any individual logic board cuts across the edges of all the logic boards on the other side. A first plurality of printed circuit boards connected to the first connectors are connected to a second plurality of printed circuit boards connected to the second connectors using double-ended and single-ended pins which pass through the midplane board. This arrangement of pins avoids the need for significant routing of wires on the midplane itself because the pins provide direct connection to both sides of the board without the need for routing on the midplane itself.

While Sample et al. and Dara describe systems which connect orthogonally-oriented circuit boards using a midplane board, the use of pins to enable communication between the printed circuit boards presents numerous problems, both with the double-sided pins that extend outward from the board on both sides, and also with the single ended pins which extend only partially through the board. FIG. 1 illustrates a horizontal cross-section through midplane board 102, as described by Sample et al. Midplane board 102 connects a first set of connectors 104a-104c to connector 106, positioned orthogonally to connectors 104a-104c on an opposite side of board 102. A plurality of double-ended pins 108 directly connect connectors 104a- 104c to connector 106, and a plurality of single-ended pins 110 connect connector 106 to connectors 104a- 104c using short conductive traces (not shown) disposed in midplane board 102. As can be seen in FIG. 1, the cross-section of midplane board 102 is densely packed with pins 108, 110.

A first problem with the above solution is that the connection pattern between the boards on the two sides of the mid-plane utilizing only double sided pins is restricted to that which can be accomplished with only direct connection of pins between the opposite sides of the boards. If other routing patterns are needed, then a single-sided pin is utilized in conjunction with routing on the midplane to connect between a single-sided pin on one side of the midplane, and a second single-sided pin on the opposite side of the midplane.

A second set of problems is related to the mechanical size of the through pins and to the size of the hole through the midplane board. The diameter of a pin with adequate mechanical strength to serve as a pluggable connector is typically large enough that it occupies significant space on every layer of the midplane board, which is a limit on the overall routability of the board. The size of these through pins, and the requirements for a dense arrangement of these pins for increased connectability means that the pins must be packed very closely to each other. Close packing results in a small distance between pins, which limits the number of signals, i.e. routing traces, which can be routed between the pins. This is true for both double- and single-sided through pins, because even single-sided pins typically extend into the board enough to block routing on several layers. All of the traces which a designer may wish to provide in the interior of midplane board 102 are routed around the densely packed pins 108, 110 or the number of such interconnections is limited. Because of the limited available space, if additional traces are desired, additional layers must be added to midplane board 102, thereby increasing the thickness, cost, and complexity of board 102. Since increasing the density of pins is required to increase the capacity of interconnect, a tradeoff must be made between pin density and board routing capacity to provide flexible routing.

Finally, the large number of pins and connectors 104, 106 results in a fairly complex mechanical structure for midplane board 102.

Accordingly, there is a need for an improved circuit board assembly which provides a large degree of connectivity between a plurality of printed circuit boards, yet does not experience the problems and restrictions in routing associated with pass-through pins, that allows for easier placement and routing of components on the midplane board, and that allows for a denser pattern of spacing for the connection points between the midplane board and the boards which connect to the midplane board. These combined requirements are of special importance in the construction of reprogrammable, flexible logic interconnect such as for logic crossbars, typical in hardware emulators.

### SUMMARY

In accordance with an aspect of the present invention, a circuit board interconnect system comprises a midplane circuit board comprising a first side and a second side. The system further includes a first plurality of component contacts on said first side of said midplane circuit board, a second plurality of component contacts on said second side of said midplane circuit board, a first plurality of connectors, each connector in said first plurality of connectors being surface-mounted to a corresponding subset of component contacts in said first plurality of component contacts on said first side, and a second plurality of connectors, each connector in said second plurality of connectors being surface-mounted to a corresponding subset of component contacts in said second plurality of component contacts on said second side. A plurality of conductive traces are provided on or in said midplane circuit board.

In accordance with another aspect of the present invention, a reconfigurable logic system comprises a midplane circuit board comprising a first side and a second side. A first plurality of component contacts are provided on said first side of said midplane circuit board, and a second plurality of component contacts are provided on said second side of said midplane circuit board. A first plurality of connectors are surface-mounted to the component contacts in said first plurality of component contacts on said first side, and a second plurality of connectors are surface-mounted to the component contacts in said second plurality of component contacts on said second side. A plurality of conductive traces are provided on or in said midplane circuit board. A plurality of logic boards are mounted on said first side of said midplane circuit board through said first plurality of connectors, and a plurality of interconnect boards are mounted on said second side of said midplane circuit board through said second plurality of connectors. The arrangement of the boards on the two sides of the midplane can be enhanced for routing efficiency by an arrangement of the boards such that the boards on opposite sides of the midplane are substantially orthogonal to each other. That is, the boards are arranged such that the edges of the boards on one side can be viewed as cutting across the edges of a plurality of the boards which make contact on the other side of the midplane. This arrangement allows for a pattern of connections which reduces routing requirements on the midplane in a manner similar to that described in the Dara and Sample patents referenced above. The logic boards contain the logic modules which are to be interconnected and the interconnect boards contain interconnect modules for making some interconnections between logic modules. The logic boards are oriented in a first direction, while the interconnect boards are oriented in a second direction orthogonal to the first direction. The edge of each interconnect board cuts across the edges of a plurality of logic boards, which allows the interconnect between multiple logic boards to be efficiently routed through each interconnect board.

The use of surface mount connectors, and the orthogonal arrangement of boards, enable increased density of connector pins on the midplane board due to smaller pads for connection allowable on the surface of the board compared to the size of pins which pass through the board, increased capacity for routing within the midplane board due to removal of the need for pins which pass through all layers of the board and which provide barriers to routing on all layers, flexibility in the assignment and routing of signals on the midplane board due to the increased routing capacity and especially due to removal of barriers which block routing, and decreased requirements for routing on the midplane due to the orthogonal arrangement of the interconnect boards in relation to the logic boards.

### BRIEF DESCRIPTION OF THE DRAWINGS

The present invention may be better understood, and its numerous objects, features, and advantages made apparent to those skilled in the art by referencing the accompanying drawings.

FIG. 1 illustrates a cross-section of a prior art midplane board for connecting a plurality of circuit boards.

FIG. 2 is a plan view of the front side of a midplane circuit board in accordance with the present invention.

FIG. 3 is a plan view of the back side of a midplane circuit board in accordance with the present invention.

FIGS. 4a and 4b are isometric views of the front and back sides of a midplane circuit board having a plurality of logic boards and an interconnect board mounted thereon.

FIG. 4c is an isometric view of the front side of a midplane circuit board having a plurality of logic boards and interconnect boards mounted thereon in accordance with another embodiment of the present invention.

FIG. 5 is a block diagram illustrating the interconnections between the midplane circuit board, logic boards, and interconnect boards in accordance with the present invention.

FIG. 6A and 6B are isometric views of an edge connector and surface mount connector in accordance with the present invention.

FIG. 7 is a cross-sectional view of a surface mount connection.

FIG. 8 is a flowchart depicting a method for designing an electronic system that employs a midplane circuit board in accordance with the present invention.

FIG. 9 illustrates a midplane circuit board in accordance with an embodiment of the present invention.

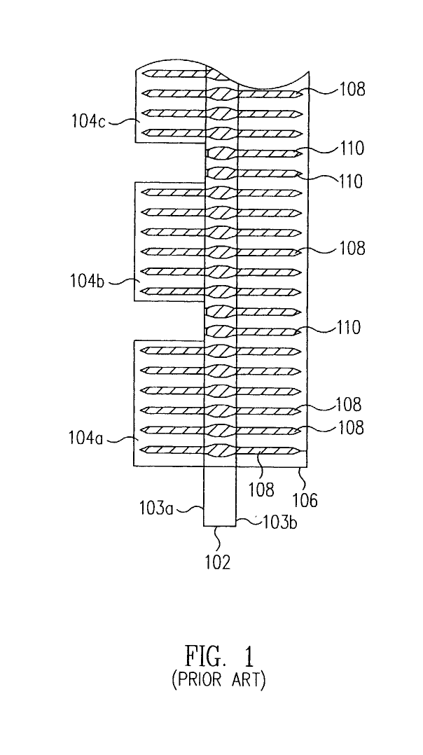

The use of the same reference symbols in different drawings indicates similar or identical items.

### DETAILED DESCRIPTION

The following description is meant to be illustrative only and not limiting. Other embodiments of this invention will be obvious to those skilled in the art in view of this description.

In accordance with the present invention, a circuit board interconnect system provides electrical connections between a plurality of circuit boards. The circuit board interconnect system includes a midplane circuit board which forms connections between logic boards mounted on the front side of the midplane circuit board via routing traces within the midplane circuit board and interconnect boards mounted on the back side of the midplane circuit board. Each logic board supports a logic module, such as a hardwired logic chip or a field programmable gate array (“FPGA”), which is to be connected to another logic module. Each interconnect board supports an interconnect module, such as a fixed interconnect chip or a FPIC, which forms the connections between logic modules.

In one embodiment, the circuit board interconnect system is used for building reconfigurable logic systems, such as a hardware emulation system. In the reconfigurable logic system embodiment, a portion of the system is reconfigurable. For example, one of the logic boards may include a reprogrammable logic module, or one of the interconnect boards may include a reprogrammable interconnect module. In the design of a machine intended for providing reconfigurable logic and reconfigurable interconnect, interconnect paths from each circuit board to a plurality of other circuit boards are required. Such connection requirements, i.e. where many boards are connected with multiple interconnect paths to many other boards, requires a large number of wires which must cross through a central routing area on the interconnect system.

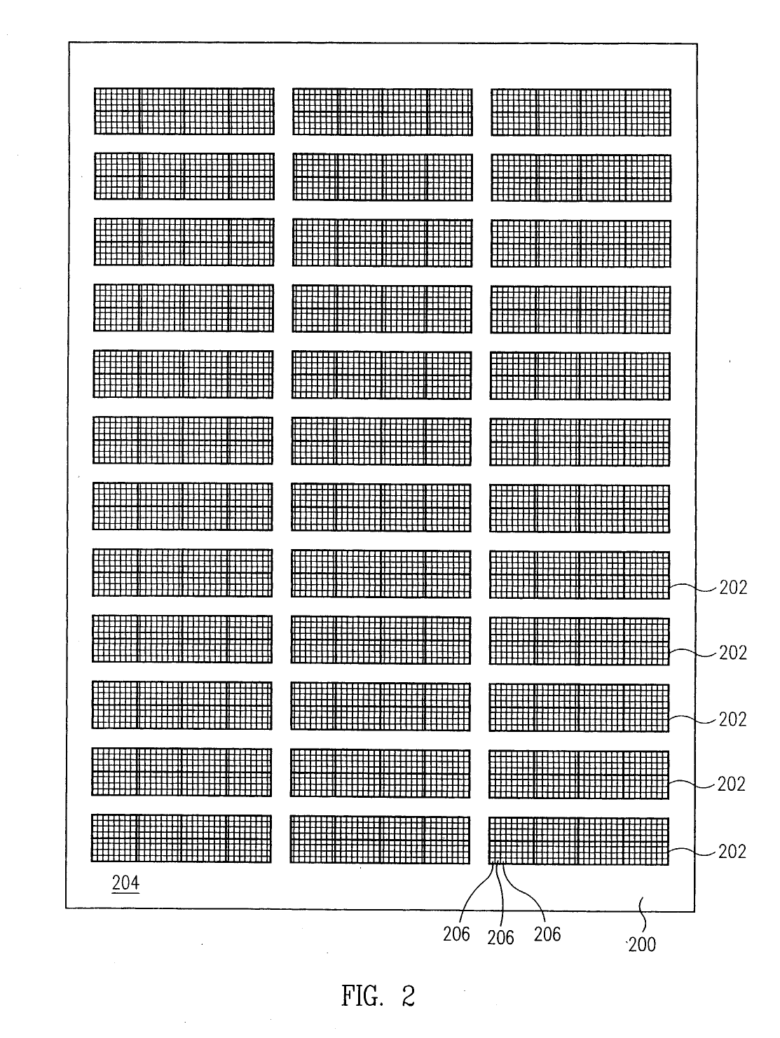

FIG. 2 illustrates in top view a midplane circuit board 200 having a plurality of contact regions 202 formed on a front side 204 of midplane board 200, in accordance with an embodiment of the present invention. Contact regions 202 are formed in, for example, twelve horizontally arranged rows, each row having three contact regions 202. Each contact region 202 includes an array of component contacts 206, which provide electrical connections to boards mounted on midplane board 200.

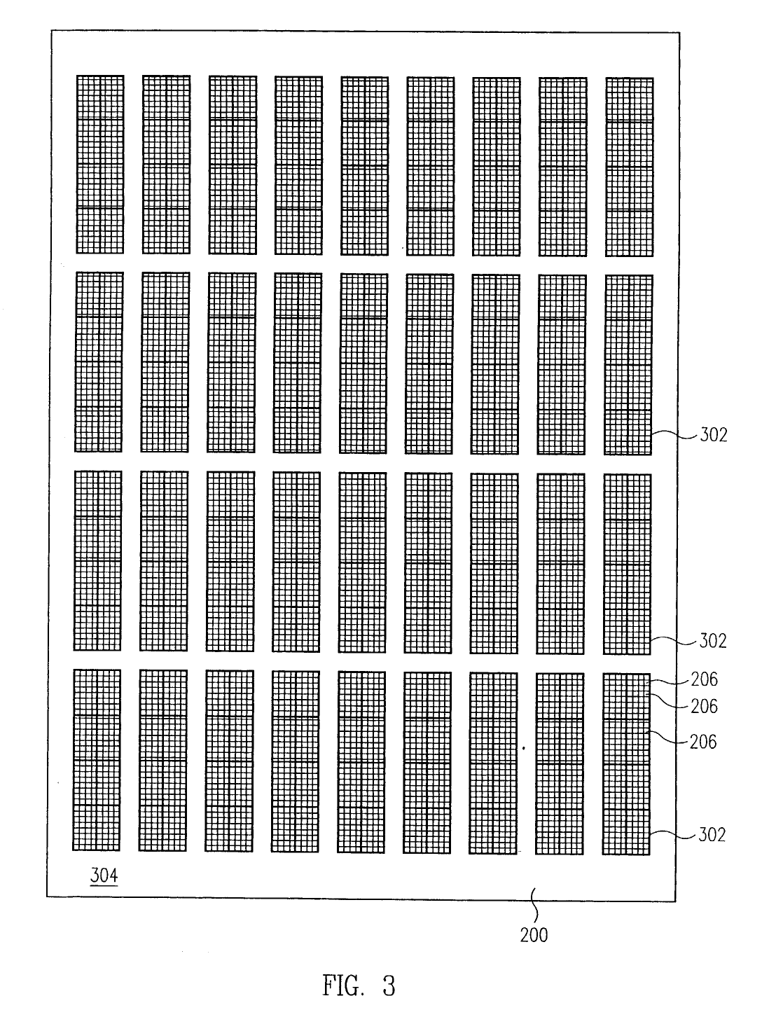

FIG. 3 illustrates in top view a back side 304 of midplane circuit board 200. Contact regions 302 are formed in, for example, nine columns, each column having four contact regions 302. Contact regions 302 also include an array of component contacts 206 and are substantially similar to contact regions 202, but contact regions 302 are oriented in columns arranged in a vertical direction orthogonal to the orientation of contact regions 202. In one embodiment, the embodiment illustrated in FIGS. 2 and 3, each contact region 202 and 302 has an 8×32 array of component contacts, though different numbers of component contacts per contact region may be used.

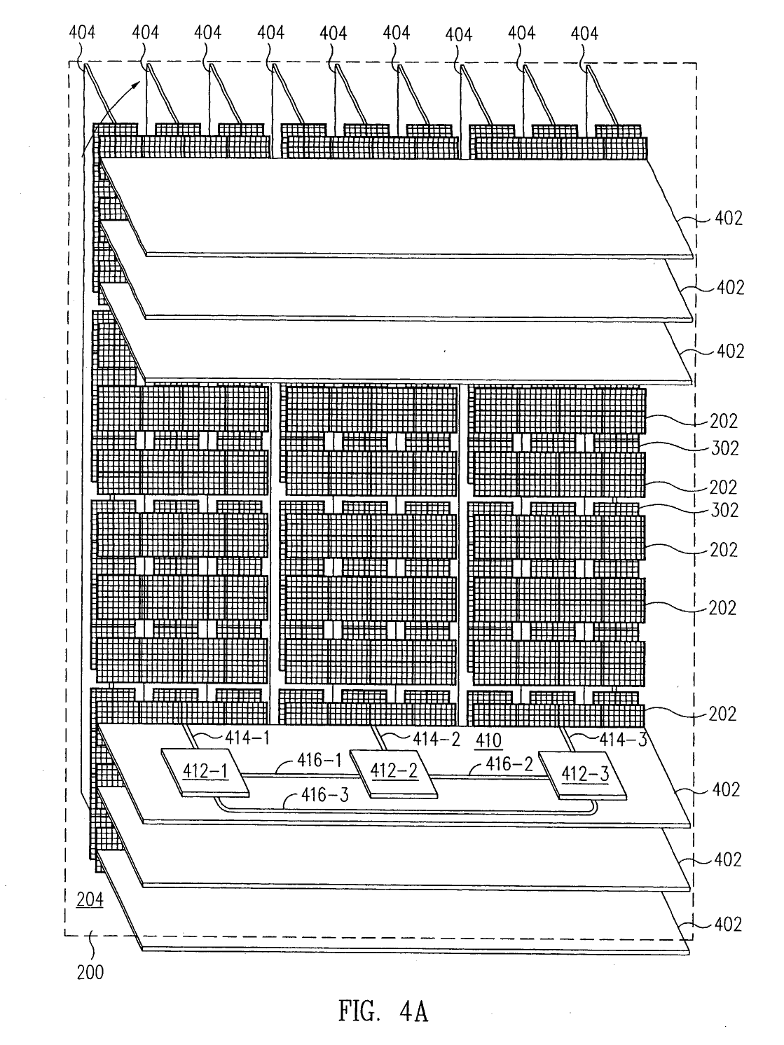

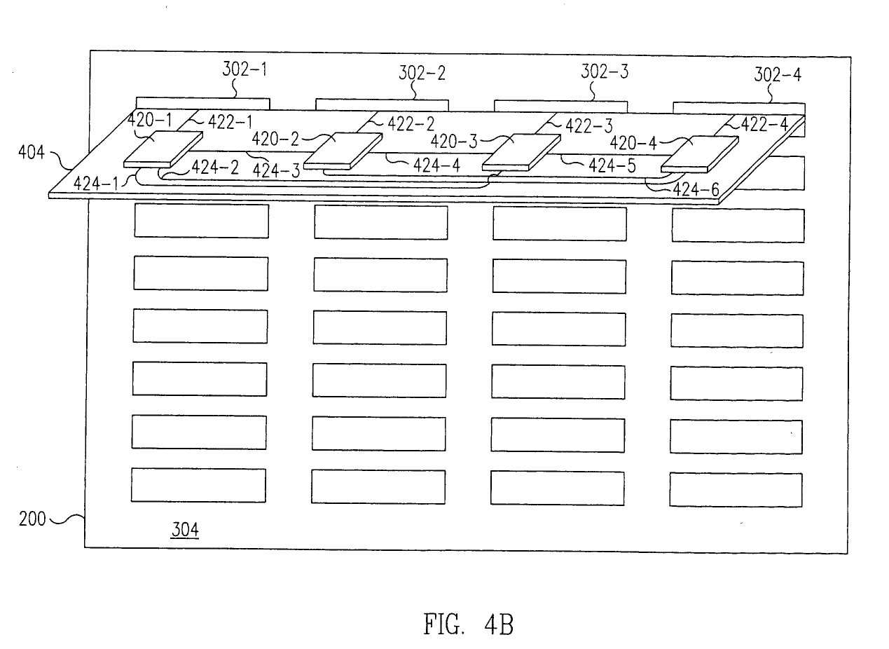

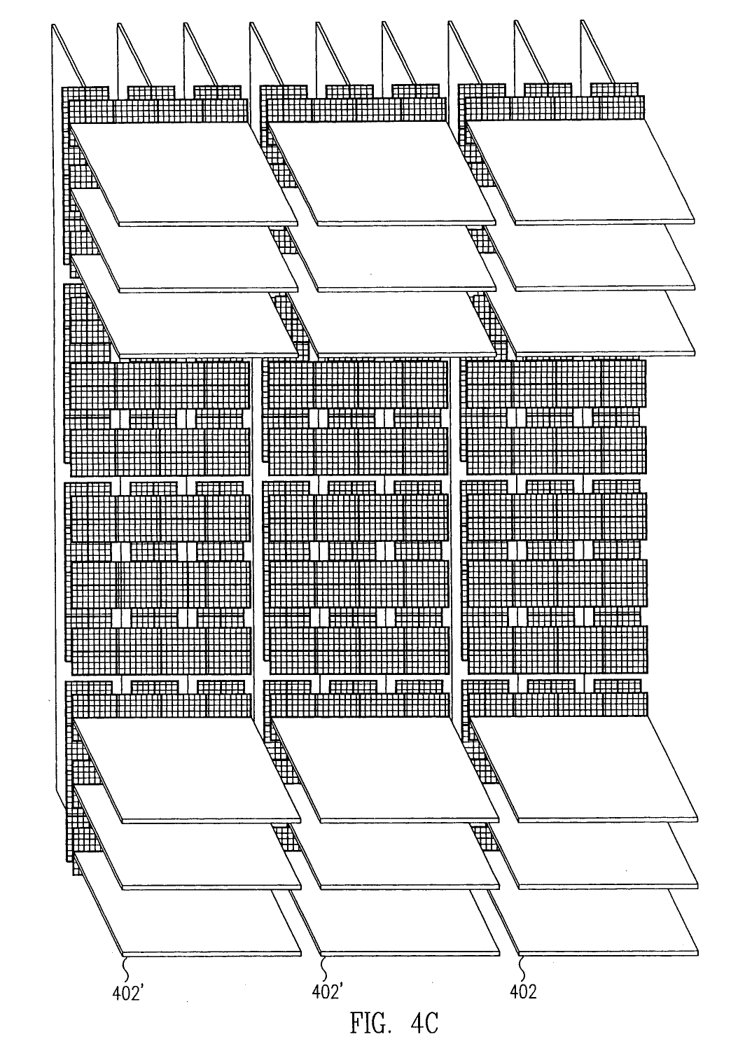

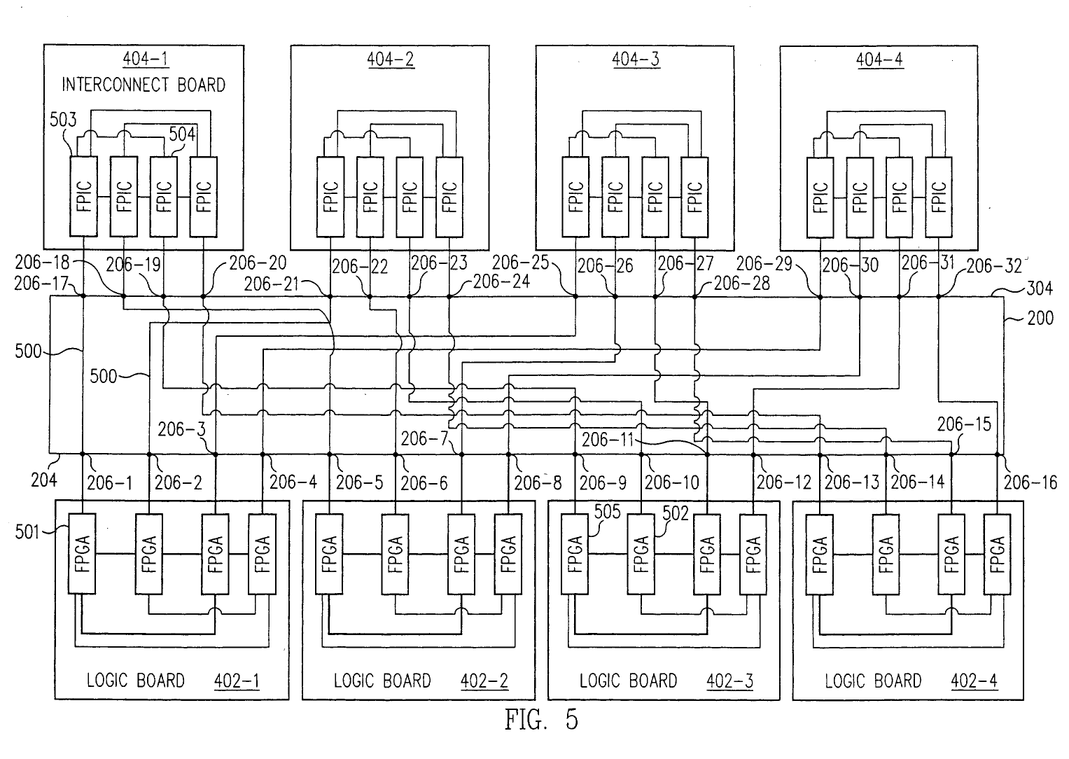

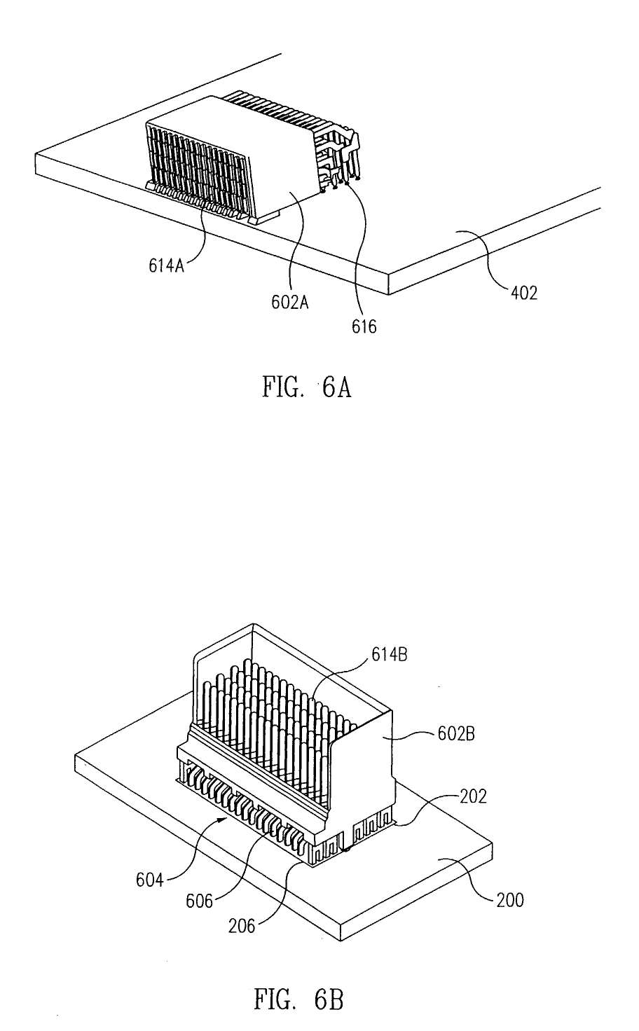

Midplane circuit board 200 is used to form electrical connections between a plurality of logic boards 402 and a plurality of interconnect boards 404, as shown in simple block form in FIGS. 4a, 4b, and 5. FIG. 4a illustrates, in isometric view, contact regions 202 on front side 204 of midplane circuit board 200. In FIG. 4a, midplane circuit board 200 is shown in phantom lines so that contact regions 202 on the front side and contact regions 302 on the back side can be viewed simultaneously. FIG. 4b illustrates, in isometric view, back side 304. Each row on the front side 204 includes one logic board 402 which is connected with three contact regions 202 through connectors (not shown in FIGS. 4a-4b) as will be described below in reference to FIGS. 6A and 6B. On back side 304 of midplane board 200, each column includes one interconnect board 404 which is connected with four contact regions 302 through connectors not shown in FIGS. 4a-4b.

Logic boards 402 can be provided in a variety of forms, as understood by one skilled in art. In one embodiment, logic board 402 includes a substrate 410 on which logic modules are mounted. “Logic module” refers to any component which may be connected to logic board 402 which includes logic, for example, fixed logic chips, programmable logic chips, or boards on which are mounted fixed or programmable logic chips. Typically, logic modules are field programmable gate array (“FPGA”) chips 412. FPGA chips 412 may be, for example, Virtex FPGAs available from Xilinx of San Jose, Calif.

Each FPGA chip 412 is connected to contact regions 202 through board interconnects 414. Board interconnects 414 connect pins of FPGA chip 412 to electrical contacts on an edge connector (not shown) of logic board 402. This edge connector on logic board 402 mates with connectors surface-mounted on midplane board 200, as will be described in greater detail below with respect to FIGS. 6A and 6B.

In some embodiments, chip-to-chip interconnects 416 are also provided on logic board 402 to provide direct interconnections between some pins of FPGA chips 412. Chip-to-chip interconnects 416 may be wire traces, which are fast but inflexible connections, or interconnect chips (“FPICs”), described below, which are slower but more flexible connections. Routing signals directly between FPGAs through chip-to-chip interconnects 416 is faster than routing signals through midplane board 200. Accordingly, chip-to-chip interconnects may be used where signals must be passed between two FPGAs located on the same logic board. The pins of a given FPGA may thus be connected to the midplane board, to chip-to-chip interconnections, or to both.

On back side 304, shown in FIG. 4b, each column of four contact regions 302 is connected with an interconnect board 404. For simplicity, only one interconnect board 404 is illustrated in FIG. 4b. In one embodiment, interconnect board 404 includes a substrate on which interconnect modules are mounted. “Interconnect module” refers to any component which may be connected to interconnect logic board 404 which is capable of making interconnections. Typically, an interconnect module is an FPGA, as described above, or an interconnect chip (also referred to as a “PIC” or an “FPIC”). In the embodiment illustrated in FIG. 4b, each interconnect board 404 includes four PICs 420. An exemplary interconnect board 404 and chips 420 can be constructed as described in U.S. Pat. No. 5,377,124 on an invention of Mohsen, entitled “Field Programmable Printed Circuit Board,” and U.S. Pat. No. 5,973,340 also on an invention of Mohsen, entitled “Interconnect Substrate with Circuits for Field-Programmability and Testing of Multichip Modules and Hybrid Circuits,” both assigned to the same assignee as this invention and incorporated herein by reference. By providing multiple chips 420 on a single interconnect board 404, common control lines such as controls for the initialization of interconnect chips 420 and power can be shared by all of the chips 420 on the board.

On-board chip-to-chip routings 424 may also be provided on interconnect board 404, as shown in FIG. 4b. These chip-to-chip routings 424 allow direct routing between PICs 420-1, 420-2, 420-3, and 420-4, thereby reducing the routing load on midplane board 200 and increasing speed. While the addition of routings 424 may increase the complexity of each interconnect board 404, the reduction in midplane board 200 complexity, increase in emulation speed, and greater flexibility in routing design produce an overall benefit to the system.

Board interconnects 422 on interconnect board 404 connect the leads on each PIC 420 to contact region 302 through edge connectors similar to the edge connectors mentioned above and described below in greater detail. Each interconnect board 404 extends vertically the entire length of midplane board 200 such that at least a portion of each board 404 is opposite and adjacent to each row of logic boards 402 on the front side 204 of midplane board 200.

In another embodiment shown in FIG. 4c, each FPGA chip 412 (shown in FIG. 4a, but not shown in FIG. 4c) is mounted on its own logic board 402′, such that each row includes three logic boards 402′, each logic board 402′ being connected to exactly one contact region 202. In this embodiment, direct chip-to-chip interconnects 416 are not possible because each FPGA chip 412 is on its own board 402′. Therefore, all chip-to-chip routing passes through midplane board 200. This routing may be provided on interconnect boards 404 or within midplane board 200, as will be described below.

In the embodiment described in FIG. 4c, each pin of each FPGA is available for connection to the FPGA's contact region on the midplane board. As a result, each pin of each FPGA may be connected, through the midplane board and the interconnect modules connected to the back side of the midplane board, to any other pin of any other FPGA. Accordingly, the circuit board interconnect system described in FIG. 4c is extremely flexible. In the embodiment described in FIGS. 4a and 4b, a portion of the FPGA pins are used for chip-to-chip interconnections 416. Those pins are thus reserved for signals destined for adjacent FPGAs. As a result, the circuit board interconnect system described in FIGS. 4a and 4b is less flexible than the embodiment described in FIG. 4c. However, chip-to-chip interconnections are faster than interconnections routed through midplane board 200. In addition, a circuit board interconnect system according to FIGS. 4a and 4b can accommodate more logic than a circuit board interconnect system according to FIG. 4c.

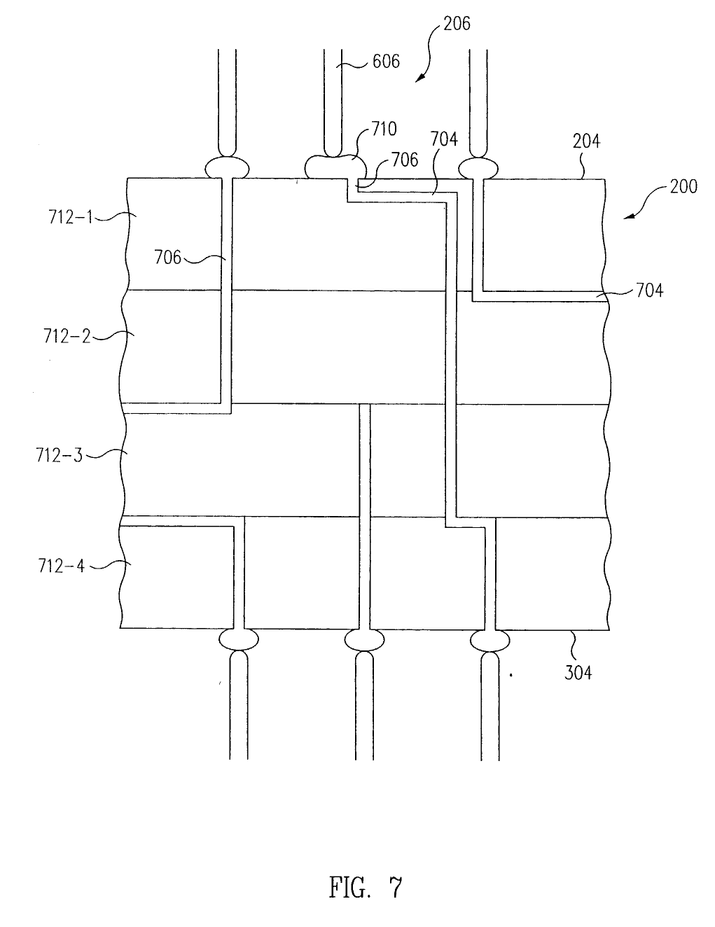

FIG. 5 is a block diagram illustrating the electrical connections between logic boards 402, midplane circuit board 200, and interconnect boards 404. One example of such connections is described in U.S. Pat. No. 5,036,473, entitled “Method of Using Electronically Reconfigurable Logic Circuits” on an invention of Butts et al., and incorporated herein by reference. Component contacts 206 on the front and back of midplane board 200 are connected through standard routing on midplane board 200, as illustrated below in FIG. 7. In some embodiments, such as that illustrated in FIG. 5, at least one component contact 206 from each front contact region 202 (not shown in FIG. 5, shown in FIG. 2) connects to at least one component contact 206 in each back contact region 302 (not shown in FIG. 5, shown in FIG. 3), though the routing on the midplane board need not be evenly distributed in this manner. In the example illustrated in FIG. 5, four interconnect boards 404-1 through 404-4 are connected to midplane board 200 by 16 component contacts 206-17 through 206-32. Four logic boards 402-1 through 402-4 are connected to midplane board 200 by 16 component contacts 206-1 through 206-17. Each interconnect board supports 4 FPICs, each connected to a single component contact. Each logic board supports 4 FPGAs, each connected to a single component contact. Each FPGA on a logic board is connected to every other FPGA on that logic board by chip-to-chip interconnections. Similarly, each FPIC on an interconnect board is connected to every other FPIC on that interconnect board by chip-to-chip interconnections.

Each interconnect board and each logic board connects to a single contact region on the back and front side, respectively, of midplane board 200. Thus, component contacts 206-1, 206-2, 206-3, and 206-4 are part of a single contact region 202 (shown in FIG. 2) on the front side 204 of midplane board 200, and component contacts 206-17, 206-18, 206-19, and 206-20 are part of a single contact region 302 (shown in FIG. 3) on the back side 304 of midplane board 200. Similarly, component contacts 206-5, 206-6, 206-7, and 206-8 are part of a single contact region 202 (FIG. 2), component contacts 206-9, 206-10, 206-11, and 206-12 are part of a single contact region 202 (FIG. 2), component contacts 206-13, 206-14, 206-15, and 206-16 are part of a single contact region 202 (FIG. 2), component contacts 206-21, 206-22, 206-23, and 206-24 are part of a single contact region 302 (FIG. 3), component contacts 206-25, 206-26, 206-27, and 206-28 are part of a single contact region 302 (FIG. 3), and component contacts 206-29, 206-30, 206-31, and 206-32 are part of a single contact region 302 (FIG. 3). FIG. 5 is a simplified view, since typically each FPIC and each FPGA would connect to more than one component contact. Further, not all the component contacts in each contact region are shown, and not all contact regions are shown.

As is illustrated in FIG. 5, a plurality of traces 500 connect a component contact in each contact region on the front side to a component contact in each contact region on the back side. For example, the first contact region on the front side includes component contacts 206-1 through 206-4. Component contact 206-1 is connected to component contact 206-17 in the first-contact region on the back side, component contact 206-2 is connected to component contact 206-21 on the second contact region on the back side, component contact 206-3 is connected to component contact 206-25 in the third contact region on the back side, and component contact 206-4 is connected to component contact 206-29 in the fourth contact region on the back side. A component contact in each other contact region on the front side is similarly connected to a component contact in each contact region on the back side. In this manner, any FPGA can be connected to any other FPGA. For example, FPGA 501 is connected to FPGA 502 as follows: FPGA 501 is connected to FPIC 503 by a trace 500 through midplane board 200. FPIC 503 is connected to FPIC 504 by a chip-to-chip interconnect on interconnect board 404-1. FPIC 504 is connected to FPGA 505 by a trace through midplane board 200. FPGA 505 is connected to FPGA 502 by a chip-to-chip interconnect on logic board 402-3.

Traces 500 connect component contacts on the front of midplane board 200 to component contacts on the back of midplane board 200. Traces 500 must pass through midplane board 200 from the front side to the back side, but portions of traces 500 may be on the surface of midplane board 200.

In the above-described embodiments, all of the interconnect boards 404 are provided in columns on the back side 304 of midplane board 200. In another embodiment of the present invention, one or more interconnect boards are provided amongst the row of logic boards 402 on the front side 204 of midplane board 200. This interconnect board is aligned orthogonally to the interconnect boards 404 on the back side 304, and can be used to provide programmable interconnections between interconnect boards 404 on back side 304 without using logic boards 402 for routing.

In another embodiment, all of the boards on the back side 304 need not provide programmable interconnections. Instead, a hardwired interconnect board, i.e. an interconnect board containing a series of fixed wire traces, can be used to provide a fixed wiring scheme to connect multiple logic boards 402. A hardwired interconnect board provides connections between logic boards which are faster than FPICs, but less flexible. The choice between a fixed interconnect module such as a hardwired interconnect chip or a programmable interconnect module such as a FPIC can be made by the user of the system.

Turning now to FIGS. 6A and 6B, as described above, logic boards 402 and interconnect boards 404 are connected to contact regions 202, 302 using edge connectors 602A on boards 402, 404. Edge connectors 602A are fitted into connectors 602B, which are surface mounted onto contact regions 202, 302 of midplane board 200. Exemplary connectors 602A and 602B are shown in isometric view in FIGS. 6A and 6B. In the embodiment described in FIGS. 6A and 6B, connector 602B includes an array 604 of pins 606 that protrude from a bottom surface of connector 602B. Pins 606 are also referred to as “connectors.” Each pin 606 mates with a corresponding component contact 206 using surface mounting techniques, to provide connections between connector 602B and midplane board 200. On the surface of connector 602B opposite the surface mounts is an array of pins 614B. Pins 614B mate with slots 614A in edge connector 602A, connected to board 402. Edge connector 602A is illustrated in FIG. 6A. Edge connector 602A is connected to board 402 by pins 616, which are soldered to board 402.

In some embodiments, connectors 602A and 602B are DensiPac® connectors, available from Tyco Electronics EC GmbH & Co. KG, D-81739 Munich, Germany. Other types of surface mounting are possible, as would be understood by one skilled in the art.

The words “surface mounted” mean that the connectors attached to the midplane board contact the midplane board primarily through contact points on the surface of the midplane board. The connection points do not extend through the board, or significantly into the underlying routing structure except for the connection to the midplane board routing. FIG. 7 shows a cross-section of an exemplary surface mount and a cross section of selected connections in midplane board 200 between component contacts on front side 204 and back side 304. Pin 606 is electrically and physically connected to solder mass 710. Solder mass 710 connects to a routing trace 704 within midplane board 200 through via 706. Pin 606 of connector 602B (FIG. 6B) is electrically and physically connected with via 706 and trace 704 through solder mass 710. Pin 606 does not penetrate midplane board 200 and does not pass from the front side 204 of midplane circuit board 200 through to the back side 304.

Midplane board 200 is comprised of several layers 712-1 through 712-4. Four layers are illustrated in FIG. 7, though more or fewer layers may be necessary to connect the component contacts on the front side with the component contacts on the back side, depending on the size of midplane board 200 and the complexity of the connection scheme. If each front side component contact is to be connected to a back side component contact that is directly opposite the front side component contact, very few layers may be necessary. In contrast, if each front side component contact is far away from the back side component contact to which it is to be connected, each trace would have to cross many other traces, thus requiring, for example, three or more layers to keep the traces electrically isolated from each other. A connection is formed between a component contact on front side 204 and a component contact on the backside 306 by one or more traces 704, which connect to one or more vias 706. A trace makes a connection between two points on a single layer, while a via connects points on different layers. Given enough layers 712, traces and vias can be formed within midplane board 200 to connect any component contact on front side 204 to any component contact on back side 304.

The above-described embodiments offer several advantages over the prior art systems. First, the electrical connections between logic boards 402 on the front side 204 of midplane board 200 and interconnect boards 404 on the back side 304 do not utilize pins which pass from the front side 204 to the back side 304. Instead, surface mounting and interconnects within midplane board 200 (vias and traces) are used to provide electrical connections from connectors 602B to contact regions 202. As a result, the connection pattern between boards on the front and back sides is not limited to direct connections from pass-through pins. Rather, through interconnect traces and vias within the midplane board, any board on the front side can be connected to any board on the back side.

Second, the above-described circuit board structure advantageously provides a high-density interconnect structure which efficiently routes signals between logic boards 402 using interconnect boards 404. The connection pins used in prior art interconnect boards undesirably consume precious routing space within the midplane board 102. Because the connection pins in the prior art system pass entirely through the midplane board, the apertures for receiving these pins are bulky and prevent highly dense connections. In addition, when the density of these pins increases, less room is available for trace routings within the midplane board. Further, the pass-through pins must be large enough to physically support boards mounted on the midplane board.

In contrast, an interconnect system in accordance with the above-described embodiment of the present invention uses surface mounting which does not intrude into the inner layers of midplane board 200. Therefore, the inner layers can be fully utilized for interconnect routing without having to circumvent pass-through holes for connection pins. In addition, the traces and vias in midplane board 200 need only be large enough to carry an electrical signal, in contrast with the prior art pass-through pins, which have to be much larger in order to physically support boards mounted on the midplane board. As a result, a midplane board 200 according to the present invention can accommodate more interconnections than a midplane board using pass-through pins. Also, because the inner layers are more efficiently used for interconnect routing, fewer layers are required for midplane board 200, thereby decreasing system complexity and reducing cost.

FIG. 9 illustrates the amount of additional routing space available with the present invention, as compared to a prior art system which uses pass-through pins. FIG. 9 illustrates the overlap between N logic boards 402 connected to the front side of midplane board 200 and N interconnect boards 404 connected to the back side of midplane board 200. Each interconnect board and logic board has a thickness t. Where each logic board and interconnect board overlap, in shaded areas 900, pass-through pins would have been used in the prior art to connect the logic boards and interconnect boards. The area occupied by the pass-through pins for each overlap region 900 is t². Thus the total area on midplane board 200 that would be occupied by pass-through pins is t²N², as there are N interconnect boards and N logic boards, meaning there are N² overlap regions. As is described above, little or no routing can be placed in the areas where pass-through pins are used, because of the size of the pins. Thus, in the prior art system, the area available for routing is the area of the midplane board minus the area occupied by the pass through pins, or LW−t²N². Because the present invention does not use pass-through pins, the entire area of the midplane board, LW, is available for routing. The ratio of the area available for routing in the prior art to the area available for routing in the present invention is given by 1−t²N²/LW.

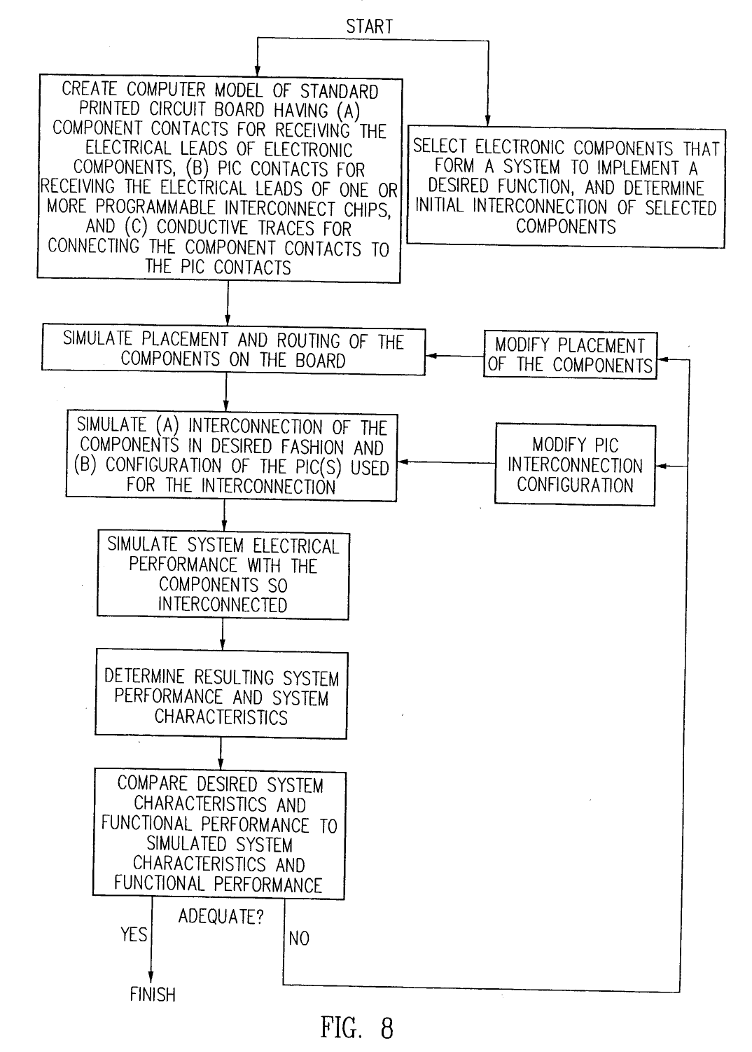

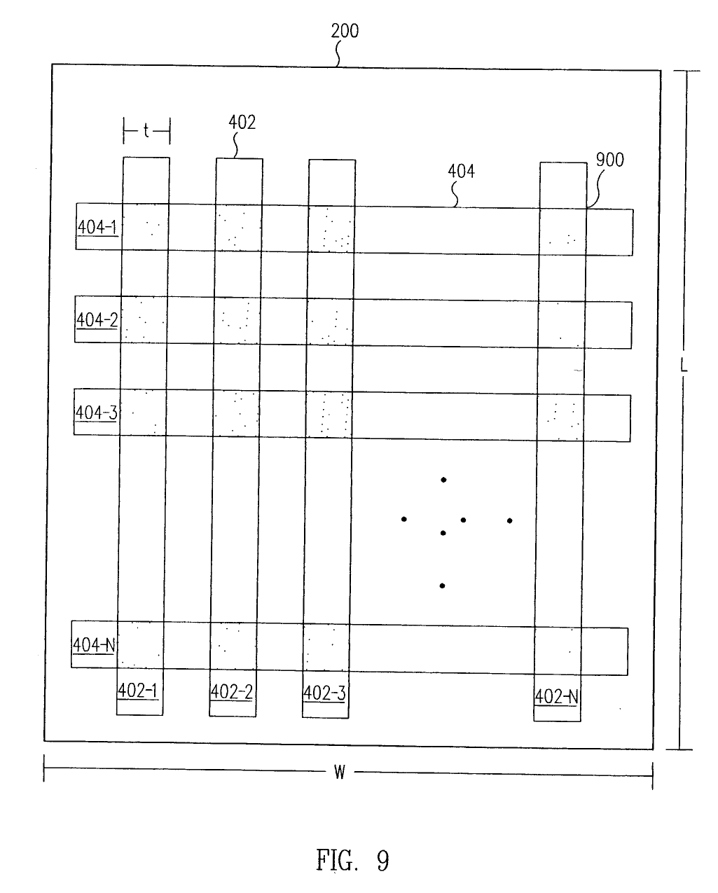

FIG. 8 illustrates how a hardware emulation system in accordance with this invention is utilized to assist in the verification and modeling of an electronic logic system. The designer constructs a logic model of the system to be simulated. The designer divides the model into pieces that can be contained within the logic boards of the hardware emulation system. A computer program may be used to assist in the partitioning of the model into logic boards. Either the designer or a computer program determines the interconnect between logic boards to implement the system level logic model. A computer program is used to determine the programming of the interconnect boards and logic boards necessary to implement the desired interconnect and the logical model. The logic model is loaded into the emulation system by programming all the programmable elements, such as FPGAs on the logic boards and the FPICs which determine the interconnections on the interconnect boards. The logic system is simulated using either internally loaded stimulus or stimulus from an external source. The system's functional behavior and performance are analyzed to determine if the desired results are achieved. If the results are not as desired, the logic equations or the implementation of the model in the hardware emulation system are modified, and testing is repeated until the desired results are achieved.

Algorithms for use in a computer aided design system of the type used to implement the design of electronic systems in accordance with this invention are currently available in the electronic design industry.

The above embodiments only illustrate the principles of this invention and are not intended to limit the invention to the particular embodiments described.

For example, all of the logic boards 402 need not be provided on only one side of midplane circuit board 200. Logic boards 402 may be placed on both sides of midplane board 200. Similarly, interconnect boards 404 may be placed on both sides of midplane board 200 as well. These and various other adaptations and combinations of features of the embodiments disclosed are within the scope of the invention, as defined by the following claims.

I claim:

1. A circuit board interconnect system, comprising:
a midplane circuit board comprising a first side and a second side;
a first plurality of component contacts on said first side of said midplane circuit board, said first plurality of component contacts divided into a first plurality of contact regions arranged in rows aligned in a first direction;
a second plurality of component contacts on said second side of said midplane circuit board, said second plurality of component contacts divided into a second plurality of contact regions arranged in columns aligned in a second direction substantially orthogonal to said first direction;
a first plurality of connectors, each connector in said first plurality of connectors being surface-mounted to a corresponding subset of component contacts in said first plurality of component contacts on said first side;
a second plurality of connectors, each connector in said second plurality of connectors being surface-mounted to a corresponding subset of component contacts in said second plurality of component contacts on said second side; and
a plurality of conductive traces provided on or in said midplane circuit board.

2. The circuit board interconnect system of claim 1, further comprising:
a logic circuit board electrically connected to one of said first plurality of connectors.

3. The circuit board interconnect system of claim 2, further comprising:
a logic module electrically connected to said logic circuit board.

4. The circuit board interconnect system of claim 1, further comprising:
an interconnect board electrically connected to one of said second plurality of connectors.

5. The circuit board interconnect system of claim 4 further comprising:
an interconnect module electrically connected to said interconnect board.

6. The circuit board interconnect system of claim 1 wherein said plurality of conductive traces further comprise traces connecting a component contact in each of said first plurality of contact regions to a component contact in each of said second plurality of contact regions.

7. The circuit board interconnect system of claim 1, wherein:
said first plurality of connectors are arranged in said rows such that each of said first plurality of connectors can mate with a corresponding connector on a logic board; and
said second plurality of connectors are arranged in said columns such that each of said second plurality of connectors can mate with a corresponding connector on an interconnect board.

8. A reconfigurable logic system, comprising:
a midplane circuit board comprising a first side and a second side;
a first plurality of component contacts on said first side of said midplane circuit board;
a second plurality of component contacts on said second side of said midplane circuit board;
a first plurality of connectors, each connector in said first plurality of connectors being surface-mounted to a corresponding subset of component contacts in said first plurality of component contacts on said first side;
a second plurality of connectors, each connector in said second plurality connectors being surface-mounted to a corresponding subset of component contacts in said second plurality of component contacts on said second side;
a plurality of conductive traces provided on or in said midplane circuit board;
a plurality of logic boards mounted on said first side of said midplane circuit board through said first plurality of connectors; and
a plurality of interconnect boards mounted on said second side of said midplane circuit board through said second plurality of connectors.

9. The system of claim 8, further comprising:
an interconnect board mounted on said first side of said midplane circuit board for electrically connecting said plurality of interconnect boards to each other.

10. The system of claim 8, wherein:
each logic board in said plurality of logic boards comprises a plurality of programmable logic modules.

11. The system of claim 8, wherein:
each logic board in said plurality of logic boards comprises:
a substrate;
a first field programmable gate array including a first plurality of electrically conductive leads, said first field programmable gate array being mounted on said substrate;
a second field programmable gate array including a second plurality of electrically conductive leads, said second programmable gate array being mounted on said substrate; and
a plurality of electrically conductive traces formed on said substrate, each conductive trace electrically connected to a corresponding one of said first plurality of electrically conductive leads and a corresponding one of said second plurality of electrically conductive leads.

12. The system of claim 8, wherein:
each interconnect board in said plurality of interconnect boards comprises a plurality of programmable interconnect modules.

13. The system of claim 8, wherein:
said first plurality of component contacts are divided into a first plurality of contact regions arranged in a first direction; and
said second plurality of component contacts are divided into a second plurality of contact regions arranged in a second direction substantially orthogonal to said first direction.
